(19) United States
(12) Patent Application Publication
(10) Pub. No.: US 2014/0225601 A1
(43) Pub. Date: Aug. 14, 2014

(54) DEVICE AND METHOD FOR MEASURING A MAGNETIC FIELD IN AN AIR-GAP BETWEEN A STATOR AND A ROTOR OF AN ELECTRIC MACHINE

(71) Applicant: ALSTOM Technology Ltd, Baden (CH)

(72) Inventors: Maximilian HOBELSBERGER, Wurenlingen (CH); Simon Christoph HONOLD, Basel (CH); Roland Richard MOSER, Zurich (CH)

(73) Assignee: ALSTOM Technology Ltd, Baden (CH)

(21) Appl. No.: 14/135,631

(22) Filed: Dec. 20, 2013

(30) Foreign Application Priority Data
Dec. 20, 2012 (EP) 12198656.6

(51) Int. Cl. G01R 31/34

(52) U.S. Cl. CPC G01R 31/34
USPC 324/222

(57) ABSTRACT

A device for measuring a magnetic field in an air-gap between a stator and a rotor of an electric machine includes a probe to detect the magnetic field and generate a signal indicative thereof and a display unit for the signal. The probe includes a plurality of sensors.

### CROSS-REFERENCE TO RELATED APPLICATIONS

This application claims priority to European application 12198656.6 filed Dec. 20, 2013, the contents of which are hereby incorporated in its entirety.

### TECHNICAL FIELD

The present disclosure relates to a device and method for measuring a magnetic field in an air-gap between a stator and a rotor of an electric machine.

The electric machine is in particular a rotating electric machine such as a synchronous generator to be connected to a gas or steam turbine (turbogenerator) or a synchronous generator to be connected to a hydro turbine (hydro generator) or an asynchronous generator or a synchronous or asynchronous electric motor or also other types of electric machines.

### BACKGROUND

The stators of large electric generators and motors are routinely tested to detect possible interlamination short-circuits.

For example the so-called low-energy test can be used, also known as the “EL CID” test. For this test the stator-core is magnetized to low magnetic flux densities (e.g. 0.1 T), and the surface of the stator bore is scanned to detect magnetic flux generated by eddy currents; these eddy currents are caused by interlamination short-circuits. The detected magnetic flux is then interpreted to detect interlamination short circuits.

In order to carry out this test, an inspection device is placed in the air-gap between the rotor and the stator.

Inspection devices have conventional probes made of one magnetic sensor being a large inductive coil.

This magnetic probe, because of its size, does not permit either accurate interlamination short circuits localization, or the determination of the magnetic field geometry.

The consequence is that the interpretation of the results can be incomplete and even incorrect.

In addition, since the air-gap width is normally in the order of 10 to 50 mm, but at the rotor-ends it can be much smaller, for example it can be as low as 9 mm, insertion of the probe in the air-gap or driving of the probe in the air-gap can be troubling.

### SUMMARY

An aspect of the disclosure includes providing a device and a method that permit accurate interlamination short circuits localization.

Another aspect of the disclosure includes providing a device and a method that permit an accurate determination of the magnetic field geometry. This permits an improvement and simplification of the interpretation of the test results.

A further aspect of the disclosure includes providing a device whose probe can be inserted and driven in the air-gap in an easy way.

These and further aspects are attained by providing a device and method in accordance with the accompanying claims.

### BRIEF DESCRIPTION OF THE DRAWINGS

Further characteristics and advantages will be more apparent from the description of a preferred but non-exclusive embodiment of the device and method, illustrated by way of non-limiting example in the accompanying drawings, in which:

FIG. 1 is a perspective view of a device that slides on in a stator bore;

FIG. 2 is a top view of a device that slides in a stator bore;

FIG. 3 is a schematic view of a device;

FIG. 4 is a schematic view of a device with a probe in an air-gap;

FIGS. 5 and 6 are schematic views of different embodiments of the device.

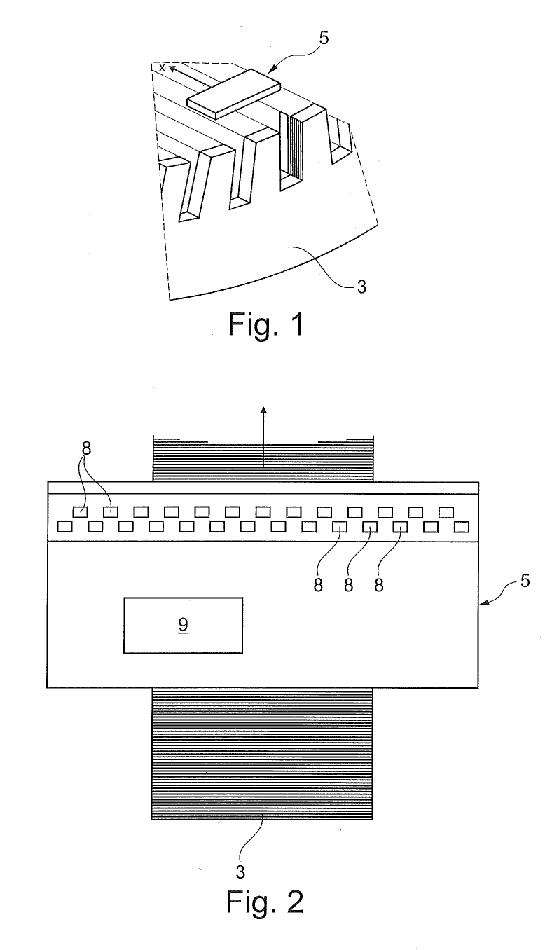

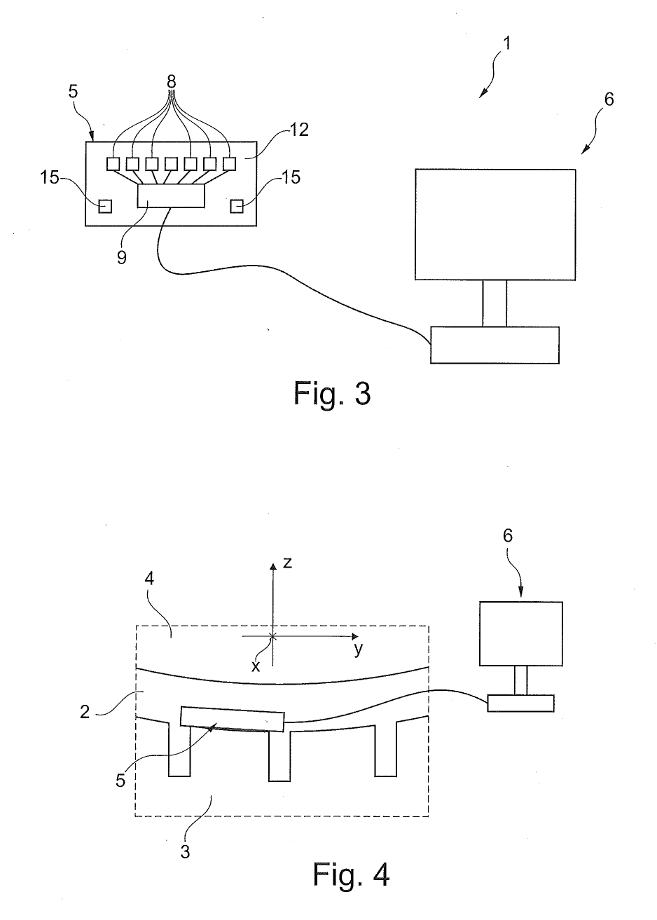

### DETAILED DESCRIPTION

The device 1 for measuring a magnetic field in an air-gap 2 between a stator 3 and a rotor 4 of an electric machine comprises a probe 5 to detect the magnetic field and generate a signal indicative thereof, and a display unit 6 (such as a PC with a dedicated software) to display the signal.

The probe 5 includes a plurality of sensors 8.

These sensors 8 are distributed close to each other in one or more rows.

For example, a probe 5 can include a row-shaped arrangement of, for example 100 sensors, which are arranged at a distance of 2 mm apart. The excessive expansion of the scope probe is therefore 200 mm.

Alternatively, the probe 5 can also have two, three or more rows of sensors 8 (these rows can be parallel or not); for example the rows extend in the direction of travel or in a direction perpendicular to the direction of travel. The individual sensors can be in this case located at a greater distance from one another, for example 6 mm. This leads to a simplification of the mechanical assembly.

The sensors are preferably connected to a circuitry 9 that collect their signals, preferably this circuitry 9 is part of the probe 5.

The sensors 8 are inductive sensors.

For example the inductive sensors are applied as a single coil on carrier plate, typically a printed circuit board with etched electrical signal and power conductors. The inductive sensors can also be formed directly on the board.

In addition, also other types of magnetic field sensors can be used, for example Hall sensors or magneto-resistive sensors (“XMR” ie GMR, TMR, AMR, etc.). These sensors are suitable due to their small dimensions and can also measure a constant magnetic field.

Also a mixture of different technologies can be used, such as coils with low spatial resolution, combined with Hall sensors with a high resolution.

In a particularly advantageous embodiment, the different sensitivity of the sensors 8 in different directions is used to determine the direction of the magnetic field.

The measurement of the direction can be carried out in all three axes of the Cartesian space, for example (with reference to a stator, see FIG. 4 in the radial direction of the stator, i.e. in a direction normal to the surface of the stator bore (z axis), in the axial direction of the stator bore and the direction of the stator grooves (x axis) and in the direction perpendicular to the xz plane (y axis), that is normal to the slot directions.

Advantageously, however, the magnetic field is measured only in two directions, namely as in z direction and in the y direction, because of the reduced amount of test data that are needed. The main direction of measurement lies on the z axis, because the local magnetic fields that are caused by the eddy currents typically emerge in this direction.

Advantageously, for the multidimensional measurements so-called “integrated” magnetic field sensors can be used; these integrated magnetic field sensors combine all the parts that are necessary for the measurement of the field in two or three Cartesian directions in an electronic component.

For example, the sensor ICs 100 of the company “Sensima Inspections” can be used. This chip also has the circuitry 9 (conversion electronics) co-integrated in it.

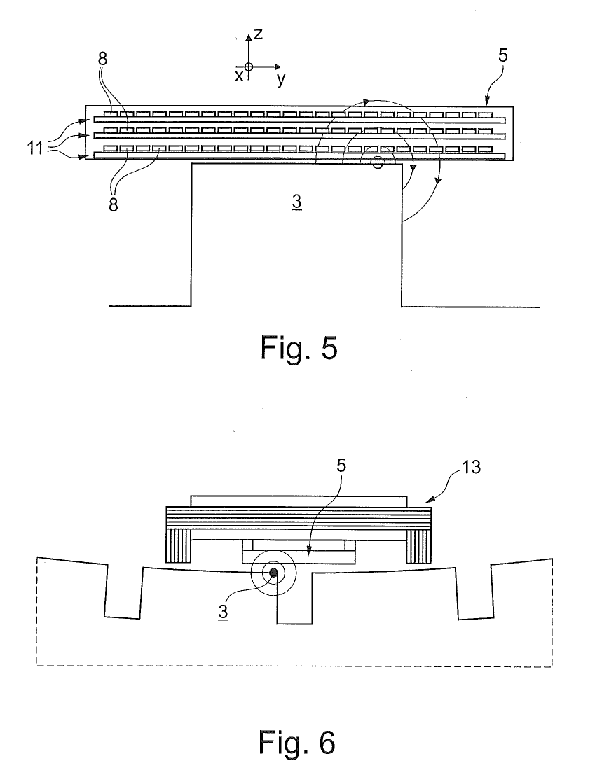

In another particularly advantageous embodiment, the sensors 8 are disposed in two or more superposed layers 11 (FIG. 5).

These layers 11 are parallel to the surface of the stator bore.

This arrangement makes it possible to measure the magnetic field, not only in a plane parallel to the stator bore surface, but in a spatial domain. Thus, the gradient of the field can be determined in a radial direction, so that the interlamination short-circuits can be located very accurately.

In particular, this embodiment enables to determine the error location in the radial direction, i.e. it helps to establish the depth at which the interlamination short-circuits lie. This can be useful because the location of the interlamination short-circuits defines the repair potential and the potential danger.

The probe can advantageously have a flexible (slightly flexible) support 12; the sensors 8 are connected to the support 12. Since the support 12 is flexible, it can be deformed, for example, to introduce it into the air-gap or to adapt it to the air gap shape (for example to the air-gap curvature).

The probe 5 can also be combined with an excitation unit 13. The excitation unit 13 is preferably small (to easily enter the air-gap 2), magnetically conductive and magnetizable.

By appropriate magnetization of the excitation unit, the stator 3 can be locally magnetized, eliminating the need of magnetization of the whole stator 3.

Because the stator 3 is in this case only locally magnetised, it can be magnetized to higher magnetic field densities without dangerous longitudinal stress.

The magnetization of the excitation unit 13 is carried out either by means of a magnetic core with a coil or by means of an electro-mechanically movable unit, e.g. a rotating magnet. The magnet can be activated by an electric motor.

In addition, also one or more infrared sensors 15 can be provided on the probe. These sensors 15 allow to detect the temperature of the stator bore surface and thus to gain further information on the stator zones where interlamination short circuits can be present (interlamination short circuits cause eddy currents and thus stator heating).

The operation of the device is apparent from that described and illustrated and is substantially the following.

The stator 3 is magnetised for example through auxiliary coils (in a traditional way). Then the device 1 is moved in the air-gap.

Since in case of interlamination short circuits in the stator 3, the magnetic field generates eddy currents that in turn generate local magnetic fields; from the detection of these magnetic fields generated by the eddy currents, the interlamination short circuits can be precisely located.

Alternatively, when the probe has the excitation unit 13, there is no need of auxiliary coils and of magnetizing the whole stator 3. In this case only selected parts of the stator 3 where the probe 5 is making the test are locally magnetised.

The present disclosure also refers to a method for measuring a magnetic field in an air-gap between a stator and a rotor of an electric machine. The method comprises providing the device 1 for measuring a magnetic field in an air-gap, magnetizing at least a portion of the stator 3, moving the device 1 on the stator bore, detecting the magnetic field generated by eddy currents that are generated by interlamination short circuits in the stator 3.

Magnetizing can include magnetizing the whole stator or locally magnetizing the stator.

By moving the probe 5 in the air-gap 2, an accurate local image of the magnetic field in the air-gap (on the surface or near the surface of the stator bore) can be obtained.

The advantages of the device and method according to the present disclosure can be summarised as follows:
thanks to the great number of sensors and their size (sub-millimetric and even micrometric scale), the spatial resolution of the measurement is greatly increased. So the actual geometry of the magnetic field generated by the eddy currents and the interlamination short circuit location can be determined with precision,
a magnetic “map” of the inspected stator surface becomes available, offering a comprehensive reporting and data interpretation tool,
the small size of the individual sensors allows to build very thin probes,
due to the multitude of individual sensors, flexible probes can be constructed which can be easily inserted into the air-gap, or which can be adapted to the stator bore curvature. This allows to manufacture and use probes which are quite large in circumferential direction,
the high-resolution picture of the surface field can be used for a more general diagnosis of the magnetic properties of the stator core in respect of homogeneity, gaps, opened teeth gaps etc.

Naturally the features described may be independently provided from one another.

In practice the materials used and the dimensions can be chosen at will according to requirements and to the state of the art.

1. A device for measuring a magnetic field in an air-gap between a stator and a rotor of an electric machine, the device comprising a probe to detect the magnetic field and generate a signal indicative thereof and a display unit for the signal, wherein the probe includes a plurality of sensors.

2. The device of claim 1, wherein the plurality of sensors are aligned along at least one row.

3. The device of claim 1, wherein the sensors include inductive sensors, preferably inductive coils.

4. The device of claim 1, wherein the sensors include Hall sensors and/or magneto-resistive sensors.

5. The device of claim 1, wherein the sensors have different sensitivity in different directions.

6. The device of claim 1, wherein the sensors define two or more superposed layers.

7. The device of claim 1, wherein the probe includes a support that carries the sensors.

8. The device of claim 7, wherein the support is a flexible support.

9. The device according to claim 1, further comprising an excitation unit for generating a localised magnetic field.

10. The device of claim 1, further comprising at least one infrared sensor.

11. A method for measuring a magnetic field in an air-gap between a stator and a rotor of an electric machine, the method comprising providing a device according to claim 1, magnetizing at least a portion of the stator, moving the device on the stator bore, detecting the magnetic field generated by eddy currents that are generated by interlamination short circuits in the stator.

12. The method according to claim 11, further comprising magnetizing the whole stator.

13. The method according to claim 11, further comprising locally magnetizing the stator.
